(19) United States
(12) Patent Application Publication
(10) Pub. No.: US 2012/0001520 A1
(43) Pub. Date: Jan. 5, 2012

(54) ACTUATOR DEVICE AND INPUT APPARATUS

(76) Inventors: Isao Takahashi, Miyagi-ken (JP); Kenichi Mitsumori, Miyagi-ken (JP)

(21) Appl. No.: 13/230,450

(22) Filed: Sep. 12, 2011

Related U.S. Application Data
(63) Continuation of application No. PCT/JP2010/055350, filed on Mar. 26, 2010.

(30) Foreign Application Priority Data
Mar. 27, 2009 (JP) 2009-079623

(51) Int. Cl. H01L 41/053; H01L 41/193

(52) U.S. Cl. 310/330

(57) ABSTRACT

An actuator device includes an actuator having one end as a fixed end and the other end as a free end, and bendable when a voltage is applied; and a base member having a fixed section that fixes the fixed end of the actuator. A projecting section is provided at the base member. In a state where the actuator is bent, when a force is applied and the free end is deformed toward a direction that is reverse to the bending direction, the actuator contacts the projecting section. The projecting section is a fulcrum of the displacement and a generating load is capable of being large by the principle of material mechanics without losing the displacement amount.

### CLAIM OF PRIORITY

This application is a Continuation of International Application No. PCT/JP2010/055350 filed on Mar. 26, 2010, which claims benefit of Japanese Patent Application No. 2009-079623 filed on Mar. 27, 2009. The entire contents of each of these applications noted above are hereby incorporated by reference in their entireties.

### BACKGROUND

1. Field of the Disclosure

The present disclosure relates to an actuator device including an actuator having one end as a fixed end and the other end as a free end, and bendable when a voltage is applied.

2. Description of the Related Art

FIGS. 14A and 14B show conceptual views (cross sectional views) describing problems of the related art.

An input apparatus 1 as shown in FIG. 14A is configured to include actuators 2, a base member 3, supporting sections 4, a key top 5 and a casing 6.

As shown in FIG. 14A, each of the actuators 2 is cantilevered to the supporting section 4. The actuators 2 are configured to have an electrolytic layer and a pair of electrode layers that are provided at both sides of the electrolytic layer in the thickness direction. Thus, when a voltage is applied between the pair of electrode layers at a fixed end side thereof, the actuators are configured so as to bend to the upper side as shown in FIG. 14A (see Japanese Unexamined Patent Application Publication No. 2005-259488).

Generally, in a bending type actuator, a displacement is difficult to make compatible with a generating load and the actuators 2 have low stiffness with low elastic modulus compared to a piezoelectric ceramic, a shape-memory alloy or the like, so that large displacement is easily obtained, while there is a problem that a large force is difficult to exert. Further, if the actuators 2 are of high elastic modulus and the thickness of the element is thickened, whilst the generating load is able to be large, the displacement amount becomes small.

In other words, when the key top 5 is pressed in the lower direction and given the sufficient displacement amount to make a state from FIG. 14A to FIG. 14B, the generating load (the generating force) that gives some degree of satisfactory pushing sensation is difficult to be obtained.

In the inventions described in Japanese Unexamined Patent Application Publication No. 2005-259488 and Japanese Unexamined Patent Application Publication No. 2008-238330, a satisfactory pushing sensation is difficult to obtain and the actuators are not sufficient to use in an input apparatus.

### SUMMARY

There is provided an actuator device including: an actuator having one end as a fixed end and the other end as a free end, and bendable when a voltage is applied; and a base member having a fixed section that fixes the fixed end of the actuator. In a state where the actuator is bent, when the actuator is deformed by a force applied to the actuator in a direction that is reverse to a bending direction with respect to the free end, a fulcrum section that is a fulcrum of the displacement is formed between the fixed end and the free end of the actuator.

According to the disclosure, in a state where the actuator is bent, the element length of the actuator is able to be sufficiently long and sufficient displacement can be obtained. Thus, when the actuator is deformed in the direction that is reverse to the bending direction, the fulcrum section that is the fulcrum of the displacement is formed between the fixed end and the free end of the actuator, and the element length from the fulcrum section to the free end is shorter than the element length from the fixed end to the free end so that the generating load is able to be large by a principle of material mechanics. As described above, in the invention, both sufficient displacement and large generating load are able to be obtained.

### BRIEF DESCRIPTION OF THE DRAWINGS

FIG. 1A shows a partial cross-sectional view of a actuator when the actuator is not operated, FIG. 1B shows a partial cross-sectional view illustrating a state where the actuator is bent and FIG. 1C shows a partial cross-sectional view illustrating a state where a free end of the actuator is pressed and the actuator and a projecting section are contacted to each other.

FIG. 2 shows a partial enlarged cross-sectional view illustrating the actuator (the polymer actuator).

FIG. 3 shows a drawing (a partial cross-sectional view) illustrating an actuator device of a second embodiment.

FIG. 4 shows a partial enlarged cross-sectional view illustrating the polymer actuator that is a portion of FIG. 3.

FIG. 5 shows a drawing (a partial cross-sectional view) illustrating a configuration of an actuator device of a third embodiment.

FIG. 6 shows a drawing describing a potential difference between electrode layers.

FIG. 7 shows a partial cross-sectional view illustrating an actuator of other embodiment.

FIG. 8 shows a partial plan view illustrating a polymer actuator and an electrode section.

FIG. 9 shows a partial cross-sectional view illustrating an actuator of another embodiment.

FIG. 10 shows a partial cross-sectional view illustrating an actuator of another embodiment.

FIG. 11 shows a perspective view illustrating an actuator of another embodiment.

FIG. 12 shows a partial cross-sectional view illustrating an actuator of another embodiment.

FIG. 13 shows a partial cross-sectional view illustrating an input apparatus of the embodiment.

FIG. 14 shows a partial cross-sectional view of an input device of the related art.

### DESCRIPTION OF THE EXEMPLARY EMBODIMENTS

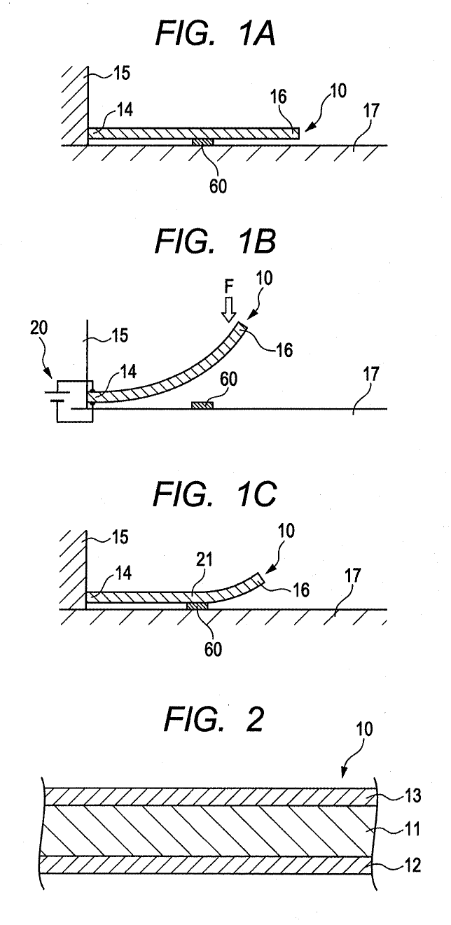

FIG. 1A to 1C show a configuration of an actuator device of a first embodiment, FIG. 1A shows a partial cross-sectional view of a polymer actuator when the actuator is not operated, FIG. 1B shows a partial cross-sectional view illustrating a state where the actuator is bent and FIG. 1C shows a partial cross-sectional view illustrating a state where a free end of the actuator is pressed and the actuator and a projecting section are contacted to each other.

As shown in FIG. 2, an actuator 10 of the embodiment is a polymer actuator configured including for example, an electrolytic layer 11, electrode layers 12 and 13 that are formed at both surfaces of the electrolytic layer 11 in the thickness direction.

The actuator 10 of the embodiment configures and includes the electrolytic layer 11 having ionic liquid and base polymer, the first and second electrode layers 12 and 13 having a conductive filler such as carbon nano tubes, the ionic liquid and a base polymer. Further, the first electrode layer 12 is an electrode layer that faces a base member 17.

As the base polymer, polyvinylidene fluoride (PVDF), poly methyl methacrylate (PMMA) or the like may be suggested. In a specific example, the ion exchange resin is not included in the electrolytic layer 11 so that both positive ions and negative ions are freely movable.

Further, the electrolytic layer 11 may include ion exchange resin and liquid organic compound that is ionic liquid or polarized organic solvent having salt. At this time, it is desired that the ion exchange resin be positive ion exchange resin. Thus, negative ion is fixed and the positive ion freely moves. As the positive ion exchange resin, it is desirable that a functional group such as sulfonic acid group and carboxyl group be introduced to resin such as polyethlyene, polystyrene and fluoro resin.

One end (a fixed end) 14 of the actuator 10 shown in FIG. 1A is fixed and supported at a fixed section 15. The actuator 10 is cantilevered and a free end 16 is supported in a state where the free end 16 is bendable to the upper side. As shown in FIG. 1B, a base member 17 is provided at a surface opposite to the bending direction of the actuator 10. The base member 17 and the fixed section 15 may be formed separately or integrally.

A projecting section (a fulcrum section) 60 is provided at the surface of the base member 17 as shown in FIG. 1A.

When a voltage is applied between the electrode layers 12 and 13 of the actuator 10 with a driving circuit 20 from the non-operation state shown in FIG. 1A, a swelling difference is generated at the first electrode layer 12 and the second electrode layer 13 side, a bending stress is generated and then the actuator 10 is bent to the upper side. In the embodiment, as an example, the first electrode layer 12 side is a negative electrode and the second electrode layer 13 side is a positive electrode. Accordingly, when the voltage is applied, the positive ion and polar molecules move to the first electrode layer 12 side. At this time, it is assumed that a positive ion is larger than a negative ion; the volume is expanded at a position that is biased to the first electrode layer 12 side. In other words, an expansion stress is generated at the first electrode layer 12 side and an expansion distortion is generated based on the expansion stress so that the bending stress is generated at the actuator 10 and the actuator 10 is bent to the upper side as shown in FIG. 1B.

As shown in FIG. 1B, when a load F is applied at the free end 16 of the actuator 10 toward the base member 17, the actuator 10 that is in the bending state is displaced toward the base member 17.

When the actuator 10 is displaced at a predetermined amount, the actuator 10 contacts the projecting section 60 as shown in FIG. 1C. The projecting section 60 is provided at a position that is opposite to a middle section 21 between the fixed end 14 and the free end 16 of the actuator 10.

In a state shown in FIG. 1C, the projecting section 60 contacts the actuator 10 and forms a fulcrum section that is a fulcrum thereof. At this time, an element length of the actuator 10 from the projecting section 60 to the free end 16 is shorter than an element length from the fixed end 14 to the free end 16. Thus, a reaction force (hereinafter, referred to as a generating load) is capable of being large when a force is further applied at the free end 16 of the actuator 10 toward the base member 17 from the state shown in FIG. 1C according to a principle of material mechanics.

Furthermore, in the embodiment, an elastic modulus is not increased or the thickness of the element is not thickened but the element length of the actuator 10 is capable of being sufficiently long to increase the generating load, the displacement of the actuator 10 is sufficiently obtained in the bending state shown in FIG. 1B. Accordingly, according to the embodiment, both sufficient displacement and a large generating load can be obtained.

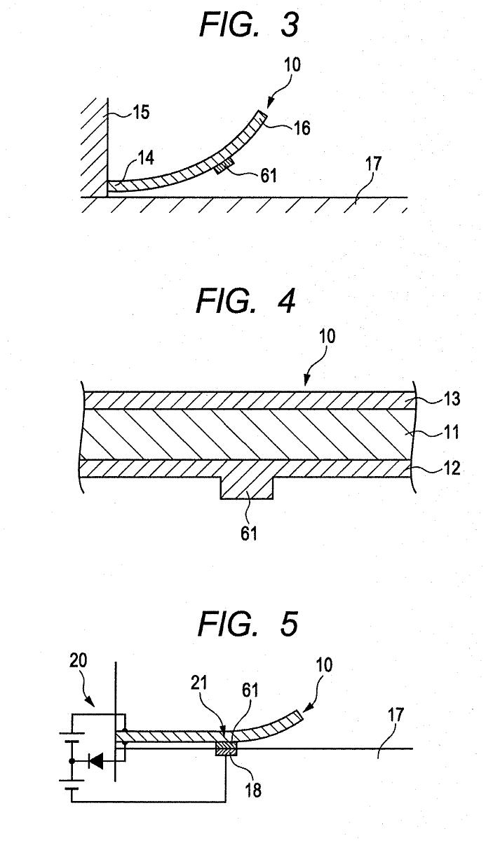

A second embodiment shown in FIG. 3 is an example in which a projecting section 61 is provided at the actuator 10 side, which is different from FIG. 1. The projecting section 61 is provided at a middle section of the lower surface (a surface that is opposed to the base member 17) of the actuator 10. In the constitution of FIG. 3, the generating load is capable of also being large similar with FIG. 1.

The projecting section 61 shown in FIG. 3 may be conductive or non-conductive. If the projecting section 61 is formed of the non-conductive material, for example, an insulating material, the projecting section 61 may be attached to the lower surface of the actuator 10 with an adhesive.

However, in the embodiment, it is desirable that the projecting section 61 be integrally formed with the first electrode layer 12 as shown in FIG. 4. Thus, the projecting section 61 is formed so as to be conductive. For example, the first electrode layer 12 and the projecting section 61 are capable of being integrally formed in a mold. Alternatively, when the first electrode layer 12 is pressed, a pressing force is decreased with respect to a formation area of the projecting section 61 so that the projecting section 61 that is integrally projected from the first electrode layer 12 is capable of being formed.

Alternatively, the projecting section 61 is individually formed with a material that is the same as that of the first electrode layer 12, and then the projecting section 61 may be for example, adhered or pressed to joint to the first electrode layer 12 integrally. As described above, the projecting section 61 and the first electrode layer 12 are integrally formed so that manufacturing costs are capable of being decreased and the projecting section 61 is not easily detached even though a force is applied to the projecting section 61 such that reliability is capable of being increased.

Further, it is desirable that the elastic modulus or the stiffness of the projecting sections 60 and 61 shown in FIG. 1 and FIG. 3 be higher than that of the actuator 10. As shown in FIG. 3, in a case where the projecting section 61 is provided at the actuator 10 side, when the members are integrally formed in a mold, the projecting section 61 may be separately casted in two steps or an aggregate such as wire is input into the structure of the projecting section 61 so that a fill charge ratio (a density) of an electrode material or the like is increased at the projecting section 61. Accordingly, since the displacement fulcrum can be firmly formed, the generating load is capable of being further effectively and stably obtained.

Further, as shown in FIG. 1, in a case where the projecting section 60 is provided at the base member 17 side, the projecting section 60 is capable of being simply formed at the surface of the base member 17 with the adhesive. If the projecting section 60 is provided at the base member 17 side and is not provided at the actuator 10 side, the actuator device may be formed in which a large generating load is capable of being obtained without changing the performance such as the displacement amount of the actuator 10.

FIG. 5 shows a partial cross-sectional view of the polymer actuator of a third embodiment. In the embodiment shown in FIG. 5, an electrode section 18 is provided at the surface of the base member 17. As shown in FIG. 5, the electrode section 18 is connected to the driving circuit 20 that is connected between the electrode layers 12 and 13 of the fixed end 14 side of the actuator 10 through a power source. A diode is provided at the driving circuit 20.

In the embodiment shown in FIG. 5, the projecting section 61 that is provided at the actuator 10 is conductive.

When the free end 16 of the actuator 10 is displaced from the bending state toward the upper side to the direction of the base member 17 due to the pressing of the free end 16 side, as shown in FIG. 5, the conductive projecting section 61 and the electrode section 18 are contacted to be conductive to each other so that a driving voltage is capable of being applied to the middle section 21 of the actuator 10. As a result, the generating load is capable of being effectively large by not only the principle of material mechanics of the projecting section 61 but also the application of the driving voltage.

As described above, in the embodiment, the materials of the first and second electrode layers 12 and 13 (FIG. 2) are not limited. A carbon film may be used or a material where an electrode material such as gold or platinum may be formed by a plating, a sputtering or the like may be used.

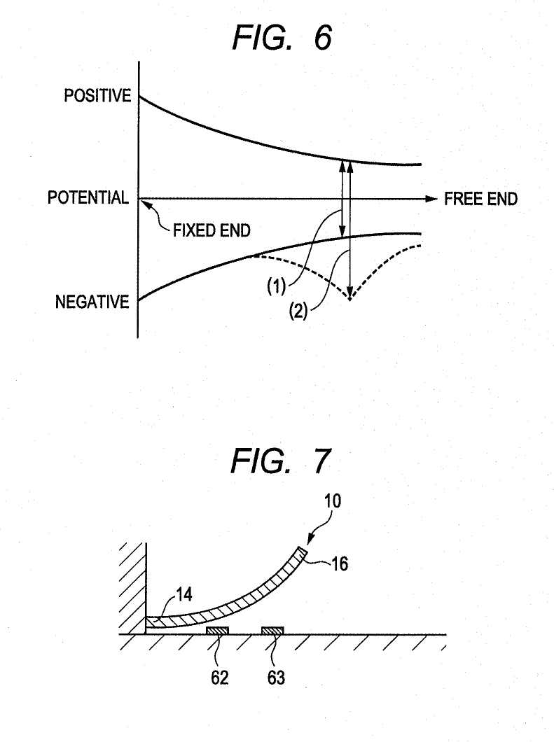

In the structure of the related art where the carbon film is used to the first and second electrode layers 12 and 13, and the electrode section 18 is not provided, as shown in FIG. 6, the voltage drop is excessively large from the fixed end 14 to the free end 16 (a solid line in FIG. 6). Accordingly, in the structure of the related art, the generating load is excessively small. A potential difference in the structure of the related art is illustrated (1) in FIG. 6.

Meanwhile, if the embodiment is used, the potential difference that is small by the voltage drop is capable of being effectively large from the middle section 21 to the free end 16 side of the actuator 10 as illustrated (2) in FIG. 6. Thus, when the embodiment is used, the generating load is capable of being effectively large even though the carbon film is used at the first and second electrode layers 12 and 13. For example, the carbon nano tube is included in the carbon film.

When the projecting section 61 of the actuator 10 contacts so as be conductive to each other, if a control is performed so as to apply high driving voltage to the middle section 21 of the actuator 10 compared to the driving voltage that is applied between a pair of electrode layers 12 and 13 from the driving circuit 20, a larger generating load is capable of being obtained after the contacting to be conductive.

As shown in FIG. 1, in a case where the projecting section 60 is attached to the base member 17 side, the projecting section 60 is capable of obtaining the same effect as that of embodiment shown in FIG. 5 even though the projecting section 60 functions as the electrode section.

As the embodiment shown in FIG. 7, a plurality of projecting sections 62 and 63 may be arranged with a gap in the direction of the free end 16 from the fixed end 14 side of the actuator 10. The configuration is formed such that the generating load is capable of being large in steps in a plurality of times according to the displacement of the actuator 10 that is bent toward the direction of the base member 17. In the configuration shown in FIG. 7, first of all, the actuator 10 contacts the projecting section 62 and the projecting section 62 forms a fulcrum section where the projecting section 62 is the fulcrum so that the generating load is capable of increasing the effect. After that, the actuator 10 contacts the projecting section 63 that is nearer to the free end 16 than the projecting section 62 and the projecting section 63 forms a fulcrum section where the projecting section 63 is the fulcrum and then larger generating load is capable of being obtained.

Both of the projecting sections 62 and 63 may be formed at the base member 17 side or formed at the actuator 10 side. Meanwhile, some of projecting sections may be formed at the base member 17 side and the rest projecting sections may be formed at the actuator 10 side.

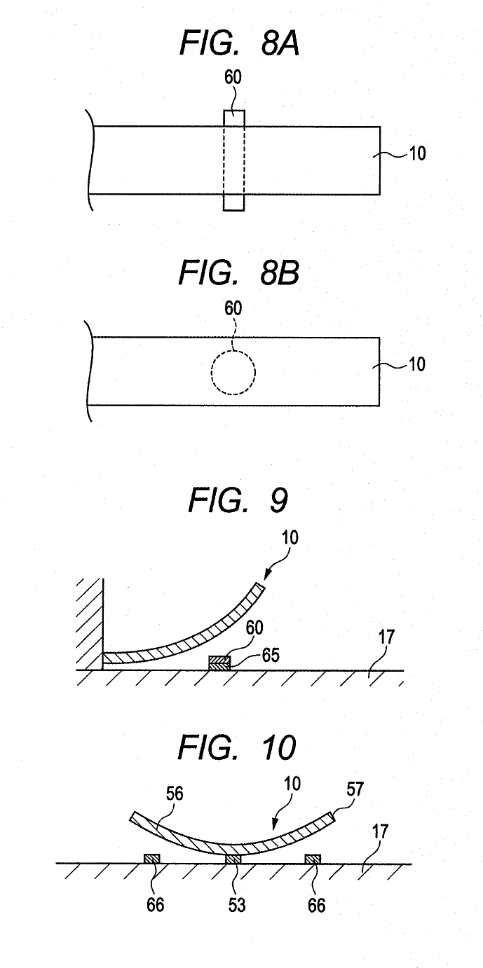

FIG. 8 shows a plan view illustrating the actuator 10 and the projecting section 60. In FIG. 8A, the projecting section 60 is extended and formed long in the width direction of the actuator 10. In FIG. 8B, the projecting section 60 is formed in a circular shape. The plan view shape of the projecting section 60 is not specifically limited, however the projecting section 60 is provided to cross the actuator 10 in the width direction as the projecting section 60 shown in FIG. 8A, so that the displacement fulcrum is capable of being provided through entire width of the actuator 10 and the generating load is capable of being more effectively large.

Further, it is desirable that the projecting section be formed near the free end 16 of the actuator 10. As described above, the projecting section is formed near the free end 16 and the fulcrum of the displacement can be near the free end 16 so that the generating load is capable of being made larger.

In FIG. 9, an elastic body 65 is interposed between the projecting section 60 and the base member 17. The elastic body 65 is provided such that when the actuator 10 contacts the projecting section 60; the elastic body 65 becomes a cushion and is capable of protecting the actuator 10 (the improvement of durability). Further, in an input apparatus described below, pushing sensation is capable of being varied. The formation position of the elastic body 65 is not limited, however, specifically, as the embodiment shown in FIG. 5, in a case where the electric contact between the electrode section 18 and the projecting section 61 is formed, it is required that the formation of the elastic body 65 does not hinder the electric contact.

The shape of the actuator 10 is not specifically limited, if the actuator 10 has the fixed end and the free end, and is capable of being bent. A shape having strips or slits is permissible.

The position that supports the actuator 10 is also not limited. For example, as shown in FIG. 10, a shape (butterfly structure) may be formed such that a fixed section 53 is provided at the middle position of the actuator 10 and both ends thereof are may be the free ends 56 and 57.

In the above description, all of the fulcrum sections are described as the projecting shape, however the fulcrum section is not limited to the projecting shape.

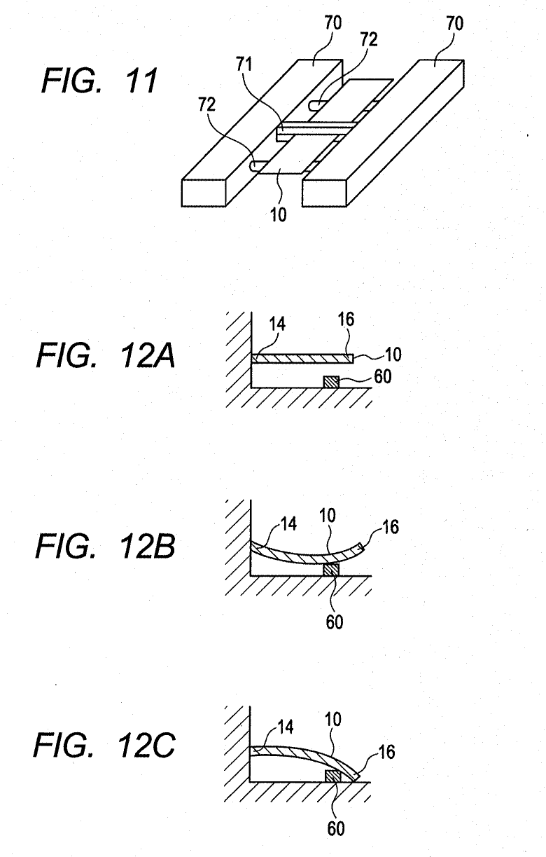

For example, as shown in FIG. 11, a configuration may be formed including base members 70 and 70 that are opposite to each other and having a gap in the width direction; a fixed section 71 that connects between the base members 70 and 70, and fixes the actuator 10; and supporting sections 72 and 72 that connect between the base members 70 and 70, are positioned at the fixed end and the free end of the actuator 10 and form a fulcrum section that is a fulcrum. In the configuration shown in FIG. 11, the supporting sections 72 and the actuator 10 are contacted through a line.

Further, as shown in FIG. 12A, the position of the formation of the projecting section 60 may be positioned more at the lower side (the position that is separated to the reverse direction of the bending direction of the actuator 10) than the fixed end 14 of the actuator 10 when the actuator 10 is not operated. When the actuator 10 is operated, the free end 16 is bent to the upper side and when the free end 16 is pressed in the lower side, the actuator 10 contacts the projecting section 60 more at the lower position than the fixed end 14 as shown in FIG. 12B. A state shown in FIG. 12C is a more pressed state than that in FIG. 12B. The displacement amount is capable of being made larger by the state shown in FIGS. 12A to 12C.

When the actuator 10 is not operated, the electrode layer of the actuator 10 and the electrode section 18 that is formed at the base member 17 may be contacted or not contacted.

In the embodiment shown in FIG. 5, the structure may be formed in which the conductivity between the projecting section 61 and the electrode section 18 is performed by a crush stress.

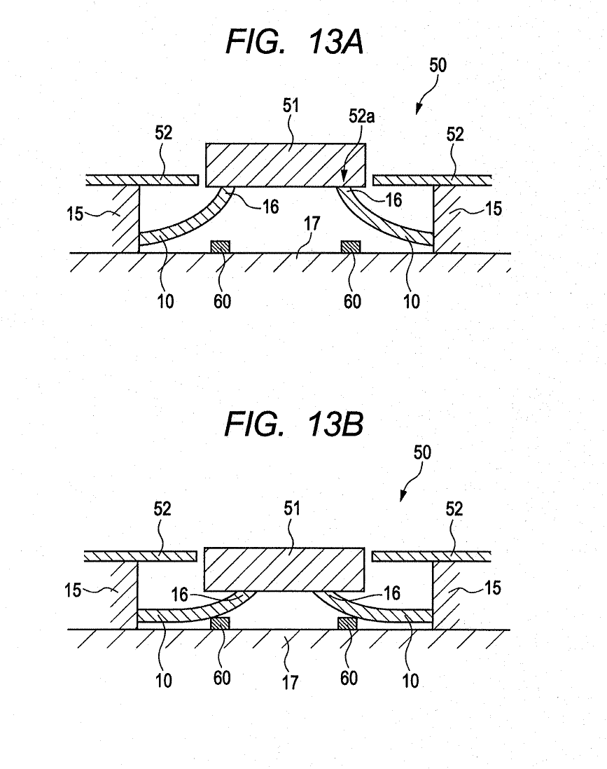

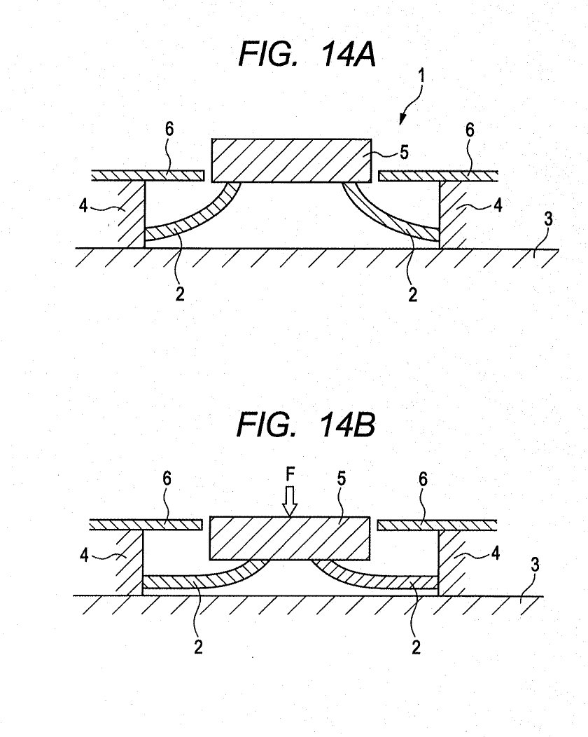

The actuator device of the embodiment may be applied to an input apparatus 50 as shown in FIG. 13. In the input apparatus 50 shown in FIG. 13, a plurality of actuators 10 is provided using the actuator device shown in FIG. 1 and the projecting sections (the fulcrum sections) 60 are provided at the base member 17. As shown in FIG. 13, a key top (an operating section) 51 is provided in the bending direction side (the upper side) of the actuators 10. The actuator device is accommodated in a case body 52 and the key top 51 is movably supported in the vertical direction through a hole 52a that is formed at the case body 52.

In the partial cross-sectional view shown in FIG. 13A, the voltage is applied between electrode layers that constitute the actuator 10, each of the actuators 10 is bent to the upper side and the key top 51 is supported to the upper side by the displacement operation of each of the actuators 10.

For example, when the key top 51 is pressed toward the lower side by the fingers of a user, the key top 51 moves to the lower side. Accordingly, the free end 16 of each of the actuators 10 is displaced toward the lower side as shown in FIG. 13B.

In the state shown in FIG. 13B, each of the actuators 10 contacts the projecting sections 60. Accordingly, since the projecting section 60s are the fulcrums of the displacement, a large generating load is capable of being obtained from the actuators 10 by the principle of the material mechanics and when the key top 51 is pressed, the pushing sensation is capable of being more satisfactory than that of the related art.

### Embodiment

A test of the generating load (the generating force) is performed using the embodiment of the actuator device that includes the projecting section at the base member and a comparison example of the actuator device that does not include the projecting section. The polymer actuator that is used in the test is tested with respect to both of the cantilever type shown in FIG. 1 and the butterfly structure.

First of all, in the case of the cantilever type shown in FIG. 1, the entire length of the actuator 10 is 5 mm and the projecting section 60 is formed at a position that is 3 mm from the fixed end 14 toward the free end 16 in the embodiment.

Further, in the case of the butterfly structure shown in FIG. 10, the entire length of the actuator 10 is 10 mm and the projecting sections 66 are formed at positions that are 4 mm at both sides from the supporting section 53 that is positioned at the center in the embodiment.

In the test, the applied voltage between the electrodes is 2V or 2.5V and the actuator 10 is bent toward the separating direction from the base member. The free end side of the actuator 10 is pressed toward the base member and then the obtained maximum generating load is calculated.

The test result is shown in Table 1.

TABLE 1

| | Comparison example | | | | Embodiment | | | |
|---|---|---|---|---|---|---|---|---|
| Applied voltage | 2 | V | 2.5 | V | 2 | V | 2.5 | V |
| Generating load | 9.6 | mN | 14 | mN | 21 | mN | 32 | mN |
| (cantilever) | | | | | | | | |
| (butterfly structure) | 19 | mN | 27 | mN | 40 | mN | 61 | mN |

The test shows that the embodiment where the projecting section is provided is capable of increasing the generating load compared to the comparison example where the projecting section is not provided.

It should be understood by those skilled in the art that various modification, combinations, sub-combinations and alterations might occur depending on design requirements and other factors insofar as they are within the scope of the appended claims of the equivalents thereof.

What is claimed is:

1. An actuator device comprising:
an actuator having one end as a fixed end and the other end as a free end, and bendable when a voltage is applied; and
a base member having a fixed section that fixes the fixed end of the actuator,
wherein in a state where the actuator is bent, when the actuator is deformed by a force applied to the actuator in a direction that is reverse to a bending direction with respect to the free end, a fulcrum section that is a fulcrum of the displacement is formed between the fixed end and the free end of the actuator.

2. The actuator device according to claim 1, further comprising:
a projecting section that forms the fulcrum section by contacting the base member between the fixed end and the free end of the actuator.

3. The actuator device according to claim 2, wherein the projecting section is integrally formed with electrode layers that constitute a polymer actuator.

4. The actuator device according to claim 1, wherein a supporting section that forms the fulcrum section is provided at the base member such that the fulcrum section contacts the actuator at a point at a portion between the fixed end and the free end of the actuator.

5. The actuator device according to claim 1, wherein the actuator has an electrolyte layer and a pair of electrodes that are provided at both surfaces of the electrolyte layer in the thickness direction, and a polymer actuator is bent when the voltage is applied between the pair of electrodes.

6. The actuator device according to claim 1, wherein the elastic modulus of the fulcrum section is higher than that of the actuator.

7. The actuator device according to claim 1, wherein the fulcrum section is formed near the free end of the actuator.

8. The actuator device according to claim 5, wherein an electrode section is provided at the base member such that when the free end of the polymer actuator that is bent is pressed and displaced in a direction that is reverse to the bending direction, the electrode section is electrically connected to the electrode layer of the polymer actuator and the electrode section is capable of applying a driving voltage.

9. The actuator device according to claim 8, wherein the electrode section serves as the fulcrum section.

10. The actuator device according to claim 1, wherein a supporting section that forms the fulcrum section is provided at the base member such that the fulcrum section contacts the actuator at a line at a portion between the fixed end and the free end of the actuator.

11. The actuator device according to claim 1, wherein the stiffness of the fulcrum section is higher than that of the actuator.

12. An input apparatus comprising:
an actuator having one end as a fixed end and the other end as a free end, and bendable when a voltage is applied; and
a base member having a fixed section that fixes the fixed end of the actuator,
wherein in a state where the actuator is bent, when the actuator is deformed by a force applied to the actuator in a direction that is reverse to a bending direction with respect to the free end, a fulcrum section that is a fulcrum of the displacement is formed between the fixed end and the free end of the actuator; and
an operating section that is provided in a direction that is opposite to a height direction of the actuator,
wherein the operating section is movably supported in the height direction, and
wherein in a state where the free end of the actuator is bent in the direction of the operating section, when the operating section moves toward the actuator and the free end is pressed and displaced in the direction that is reverse to the bending direction, a fulcrum section that is a fulcrum of the displacement is formed between the fixed end and the free end of the actuator.

13. The actuator device according to claim 12, further comprising:
a projecting section that forms the fulcrum section by contacting the base member between the fixed end and the free end of the actuator.

14. The actuator device according to claim 13, wherein the projecting section is integrally formed with electrode layers that constitute a polymer actuator.

15. The actuator device according to claim 12, wherein a supporting section that forms the fulcrum section is provided at the base member such that the fulcrum section contacts the actuator at a point at a portion between the fixed end and the free end of the actuator.

16. The actuator device according to claim 12, wherein the actuator has an electrolyte layer and a pair of electrodes that are provided at both surfaces of the electrolyte layer in the thickness direction, and a polymer actuator is bent when the voltage is applied between the pair of electrodes.

17. The actuator device according to claim 12, wherein the elastic modulus of the fulcrum section is higher than that of the actuator.

18. The actuator device according to claim 12, wherein the fulcrum section is formed near the free end of the actuator.

19. The actuator device according to claim 16, wherein an electrode section is provided at the base member such that when the free end of the polymer actuator that is bent is pressed and displaced in a direction that is reverse to the bending direction, the electrode section is electrically connected to the electrode layer of the polymer actuator and the electrode section is capable of applying a driving voltage.

20. The actuator device according to claim 19, wherein the electrode section serves as the fulcrum section.
